(19) United States
(12) Patent Application Publication
(10) Pub. No.: US 2026/0191012 A1
(43) Pub. Date: Jul. 2, 2026

(54) PACKAGE STRUCTURE AND METHOD FOR MANUFACTURING THE SAME

(71) Applicant: Taiwan Semiconductor Manufacturing Company, Ltd., Hsinchu (TW)

(72) Inventors: Kuo-Pin CHANG, Hsinchu (TW); Hung-Ju LI, Hsinchu (TW); Yu-Wei TING, Hsinchu (TW); Kuo-Ching HUANG, Hsinchu (TW)

(73) Assignee: Taiwan Semiconductor Manufacturing Company, Ltd., Hsinchu (TW)

(21) Appl. No.: 19/005,622

(22) Filed: Dec. 30, 2024

(51) Int. Cl. H01L 23/60; H01L 21/28; H01L 21/66; H01L 23/00

(52) U.S. Cl. CPC H10W 42/60; H10D 64/01338; H10P 74/207; H10W 72/0116; H10W 72/01923; H10W 72/01953; H10W 72/252; H10W 72/536; H10W 72/5522; H10W 72/5524; H10W 72/859; H10W 72/934; H10W 90/724; H10W 90/754

(57) ABSTRACT

A method for manufacturing a package structure includes the following steps. A semiconductor die is formed, the semiconductor die including a plurality of conductive pads disposed on a first surface of the semiconductor die. An electrical test is performed on the semiconductor die by the conductive pads. A phase change material layer is formed on the first surface of the semiconductor die, and the phase change material layer is electrically connected to the conductive pads. A packaging process is performed to form a conductive feature on the conductive pads of the semiconductor die. One end of the conductive feature penetrates the phase change material layer. An annealing process is performed to change the crystal of the phase change material layer from a crystalline state to an amorphous state.

### BACKGROUND

Electrostatic discharge (ESD) is the movement of static electricity from a nonconductive surface, which could cause damage to semiconductors and other circuit components in integrated circuits (ICs). The ESD may be imparted to the integrated circuits within a package structure when the integrated circuits or the package structure is contacted by an electrostatic charge source that may be encountered during assembly of the package structure.

Normally, ESD circuit is used in the integrated circuits to avoid ESD damage that releases the charges to ground of the substrate. However, since the ESD circuit must cover the largest ESD damage in package structure, the occupied area of the ESD circuit is quite large and the ESD circuit is useless after the integrated circuits are assembled on the carrier of the package structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flowchart of steps of a method for manufacturing a package structure in accordance with an embodiment of the present disclosure.

FIGS. 2A to 2D illustrate schematic diagrams of various steps for manufacturing the package structure in FIG. 1.

FIGS. 3A and 3B illustrate a flowchart of steps of a method for manufacturing a package structure in accordance with another embodiment of the present disclosure.

FIGS. 4A to 4H illustrate the schematic diagrams of various steps for manufacturing the package structure in FIG. 3.

FIG. 5 illustrates a top view of a package structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

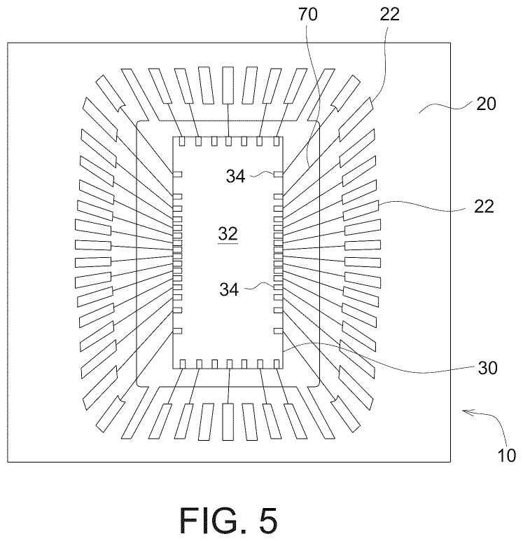

Referring first to FIG. 5, a top view of a package structure in accordance with an embodiment of the present disclosure is shown. A package structure 10 typically includes a carrier 20 (such as metal lead frame or other package substrate) coupled to a semiconductor die 30. The semiconductor die 30 includes the integrated circuit 32 which has several conductive pads 34 that couple the integrated circuit 32 to outside components. The metal lead frame or other package substrate includes a plurality of pins 22 or other contacts that are coupled to respective conductive pads 34 of the integrated circuit 32 formed on the semiconductor die 30 by wires 70. The coupling may be achieved by wire bonding to a metal lead frame, for embodiment, or it may be achieved by flip-chip packaging which involves directly joining the contact areas of the package substrate to corresponding conductive pads 34 of the semiconductor die 30 using solder bumps (not shown).

In the arrangement shown in FIG. 5, the package structure 10 includes a semiconductor die 30 coupled to a metal lead frame. In the exemplary arrangement shown in FIG. 5, the semiconductor die 30 is surrounded by and attached to the metal lead frame. Other configurations and arrangements may be used in other exemplary embodiments. In one exemplary embodiment, the carrier 20 may be a lead frame formed of metal and in another exemplary embodiment, only pins 22 of other package substrate may be formed of metal and the bulk of package substrate may be formed of another material such as a ceramic or plastic. The disclosure also applies to flip-chip packages in which the conductive pads 34 of the semiconductor die 30 are joined to corresponding pins 22 of other package substrate by direct coupling using solder bumps. Therefore, the coupling arrangement of package structure 10 is exemplary only. Various package substrates may be used to form the package structure 10 and connect the integrated circuit 32 to the outside component.

During handling, installation, testing and use in the field, the pins 22 and the conductive pads 34 are equally likely to be subjected to electrostatic discharge, i.e., zapped. When one of the pins 22 and the conductive pads 34 is subjected to ESD, it may induce ESD failure on the adjacent pins 22 and conductive pads 34 which was not zapped. More particularly, when the pins 22 and the conductive pads 34 become subjected to ESD discharge, it may damage active circuit components of the integrated circuit 32 by coupling the electrostatic discharge through the conductive pads 34 to the integrated circuit 32.

The disclosure is directed to providing a phase change material layer on a semiconductor die that includes an integrated circuit. The phase change material layer is formed of a material whose crystal changed from a crystalline state to an amorphous state, and whose electrical property changed from a low resistance to a high resistance when the phase change material layer is annealed. The phase change material layer connects all of conductive pads or bonding pads of the semiconductor die during assembly of the package structure so as to significantly improve the ESD protection capability of the semiconductor die. The disclosure also provides for forming a package structure such that each of the pins of the package structure is coupled to a corresponding conductive pad of the integrated circuit.

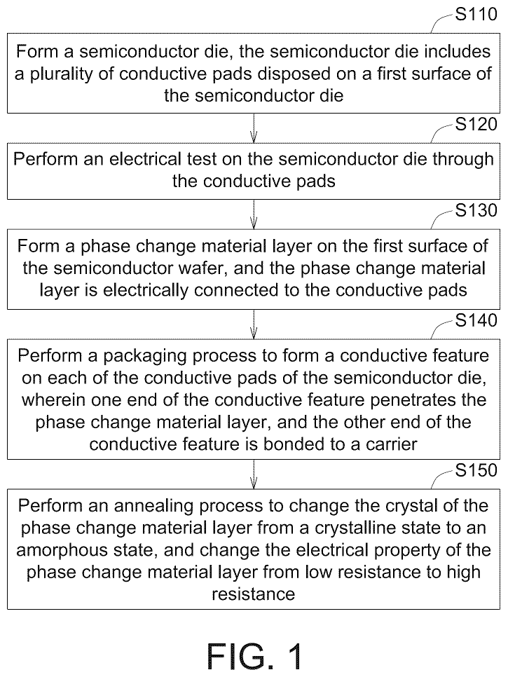

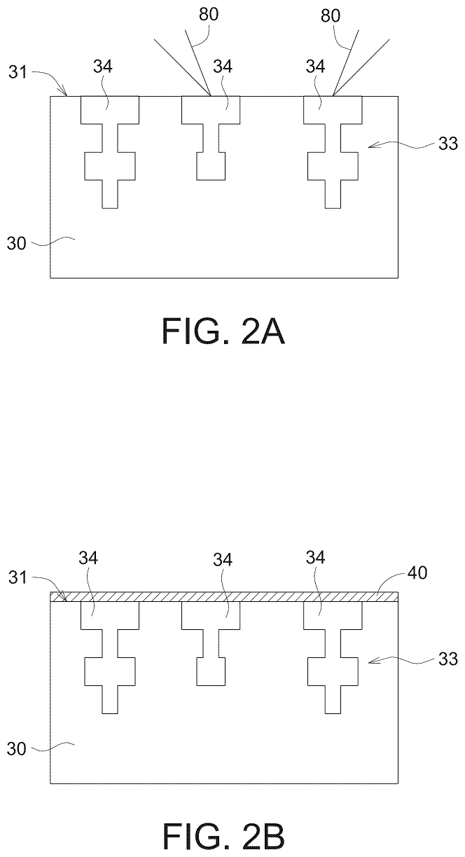

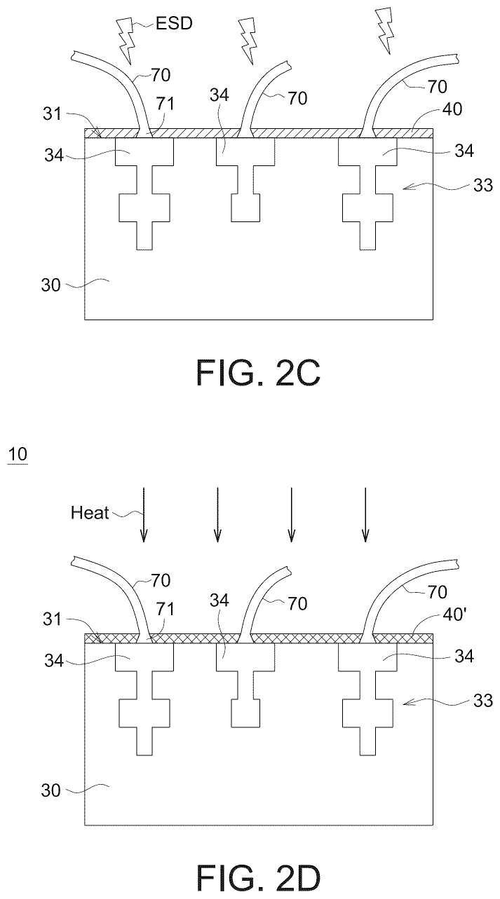

Referring to FIG. 1 and FIGS. 2A to 2D, FIG. 1 illustrates a flowchart of steps of a method for manufacturing a package structure 10 in accordance with an embodiment of the present disclosure. FIGS. 2A to 2D illustrate schematic diagrams of various steps for manufacturing the package structure 10 in FIG. 1.

Referring to step S110 of FIG. 1 and FIG. 2A, a semiconductor die 30 is formed, and the semiconductor die 30 includes a plurality of conductive pads 34, which are disposed on a first surface 31 of the semiconductor die 30. In addition, the semiconductor die 30 also includes an integrated circuit 32, shown in FIG. 5, which is electrically connected to the conductive pads 34 by an interlayer connection structure 33.

The present disclosure is illustrated by an example of manufacturing a sensor package, such as a package structure 10 for a fingerprint reader; however, it is to be understood that in the embodiment of the package structure 10 disclosed herein, it may be applied to a variety of devices comprising active or passive elements, digital or analog circuits, and other electronic components. The integrated circuit 32 is such as those relating to opto-electronic devices, micro-electro-mechanical systems (MEMS), micro fluidic systems, or physical sensors that measure changes in physical quantities such as heat, light, and pressure. In particular, the wafer scale package (WSP) process can be used for various semiconductors dies 30, such as image sensors, light-emitting diodes (LEDs), solar cells, RF circuits, accelerators, gyroscopes, micro actuators (micro actuators), surface acoustic wave devices, pressure sensors, ink printer heads, or power IC modules.

In an embodiment, the conductive pad 34 formed in FIG. 2A comprises a single conductive layer or multiple conductive layers, and the conductive pad 34 may be made of, for example, copper (Cu), aluminium (Al), or other suitable metal materials. In one embodiment, the active area or the sensing area of the semiconductor die 30 may be additionally covered with an insulating protection layer to avoid damage of the integrated circuit 32.

Referring to step S120 of FIG. 1 and FIG. 2A, the semiconductor die 30 is subjected to an electrical test by the conductive pads 34. The electrical test is performed, for example, by contacting the conductive pads 34 with a plurality of probes 80, which are used to input electrical signals to the integrated circuit 32 and to receive electrical signals output from the integrated circuit 32 in order to test the electrical performance of the integrated circuit 32.

Referring to step S130 of FIG. 1 and FIG. 2B, after completing the electrical test, a phase change material layer 40 is formed on the first surface 31 of the semiconductor die 30, and the phase change material layer 40 is electrically connected to the conductive pads 34. The phase change material layer 40 is formed, for example, by a physical vapor deposition, a chemical vapor deposition or an atomic layer deposition. Before the semiconductor die 30 is packaged, the phase change material layer 40 is deposited on the first surface 31 and electrically connected to the conductive pads 34 so that the conductive pads 34 have the same potential. Since all of the conductive pads 34 have the same potential, even if one of the conductive pads 34 on the semiconductor die 30 is subjected to an electrostatic discharge attack during wafer packaging, the electrostatic discharge can still be transmitted to the other conductive pads 34 through the phase change material layer 40, and thus dielectric breakdown and damage to the integrated circuit 32 can be avoided.

In one embodiment, the phase change material layer 40 comprises a conductive material, such as a metal alloy, which electrically connects all the conductive pads 34 to a ground wire to conduct an incoming static current to the ground terminal. The phase change material layer 40 may be, for example, a GeSbTe alloy, a SbTe alloy, or Boron nitride (BN), etc. The phase change material layer 40 may be a sulfur compound material, such as Ge₂Sb₂Te₅ (GST). The phase change material layer 40 may also be or include other phase change materials, for example, In—Se, Sb2Te3, GaSb, InSb, As—Te, Al—Te, Ge—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Se—Te, Ge—Sn—Se—Te. Sn—Sb—Te, Ge—Te—Sn—Ni, Ge—Te—Sn—Pd, and Ge—Te—Sn—Pt. The phase change material layer 40 may also include oxygen (O), fluorine (F), nitrogen (N), and carbon (C) impurities. In other embodiments, the phase change material layer 40 may be replaced by another variable resistance material layer that does not require a phase change to change the resistance, such as NiO, TiO, CuS, and SrTiO.

In one embodiment, the phase change material layer 40 may generate a phase change between a crystalline state and an amorphous state to change the resistance value. When the phase change material layer 40 is in the crystalline state, the resistance is low so that the electrical conductivity is good; when the phase change material layer 40 is in the amorphous state, the resistance is high so that the electrical conductivity is poor. That is, when the phase change material layer 40 is in the crystalline state, it has electrical conductivity, and when the phase change material layer 40 is in the amorphous state, it has electrical insulation.

Referring to step S140 of FIG. 1 and FIG. 2C, a packaging process is performed so that a conductive feature 70 is formed on each of the conductive pads 34 of the semiconductor die 30, one end 71 of the conductive feature 70 penetrates the phase change material layer 40, and the other end of the conductive feature 70 is bonded to a carrier 20 (see FIG. 5). The packaging process may be a wire bonding process or a flip-chip packaging process. The conductive feature 70 may be a wire (e.g., gold or aluminum wire) or a conductive bump (e.g., copper alloy). For example, in a wire bonding process, a wire bonder is used to fuse one end of the wire into a ball shape and penetrate the phase change material layer 40 to bond with a corresponding conductive pad 34, and then the other end of the wire is pulled onto the carrier 20 to bond with a corresponding pin 22 of the carrier 20.

Referring to step S150 of FIG. 1 and FIG. 2D, an annealing process is performed to change the crystal of the phase change material layer 40 from a crystalline state to an amorphous state, and to change the electrical property of the phase change material layer 40 from a low resistance to a high resistance. Annealing is a thermal process used to change the microstructure of a material to change the properties of the material. For example, the crystalline phase change material layer 40 is heated so that the temperature of the phase change material layer 40 exceeds the melting point of the phase change, at which the phase change material layer 40 has a molten state, and then the liquid atoms are solidified to a solid state by a rapid cooling (such as quench) before crystallization occurs, in order to convert to an amorphous phase change material layer 40′. This amorphous phase change material layer 40′ has a resistance value much higher than the resistance value of the crystalline phase change material layer 40. Taken Ge₂Sb₂Te₅ (GST) alloy as an example, the crystalline phase change material layer 40 has a resistance value of about 25 microohms, while the amorphous phase change material layer 40′ has a resistance value of about 10³ ohms or more. In addition, the amorphous phase change material layer 40′ has, in addition to a high resistance value, a low dielectric constant, such as a smaller than the dielectric constant of silicon (about 3.5), to reduce the overall dielectric constant of the dielectric material.

As shown in FIG. 2D, the phase change material layer 40 undergoes a thermal treatment (e.g., annealing) and changes to an amorphous state, such that the conductive pads 34 are electrically insulated from each other due to a high resistance value. The amorphous phase change material layer 40′ may be used as an electrostatic discharge protection layer over the first surface 31 of the semiconductor die 30.

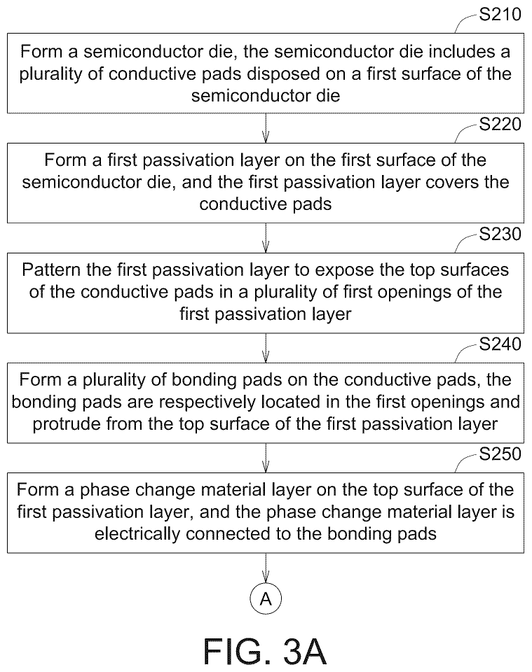

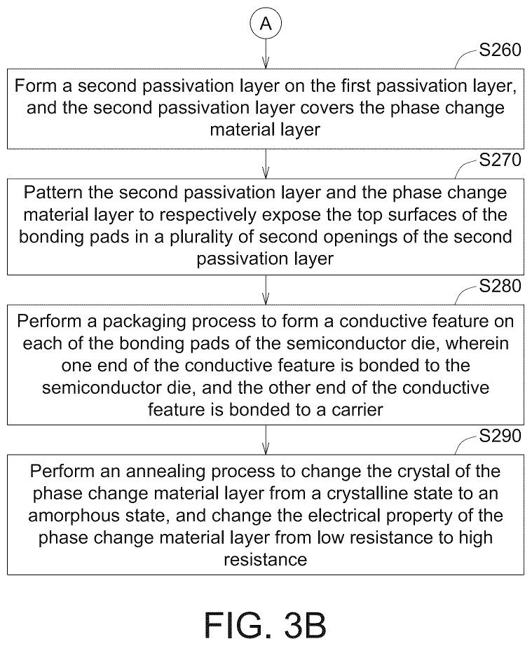

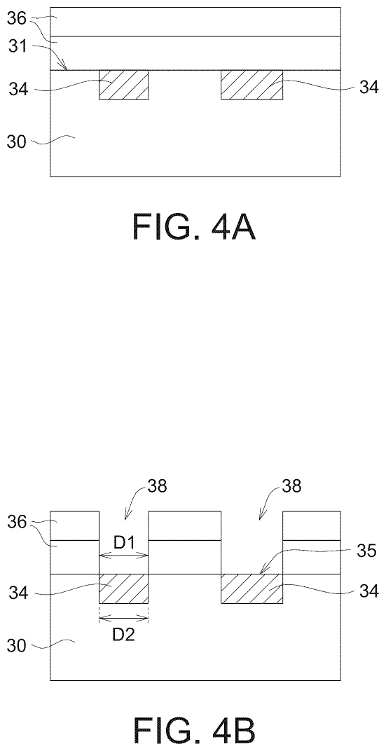

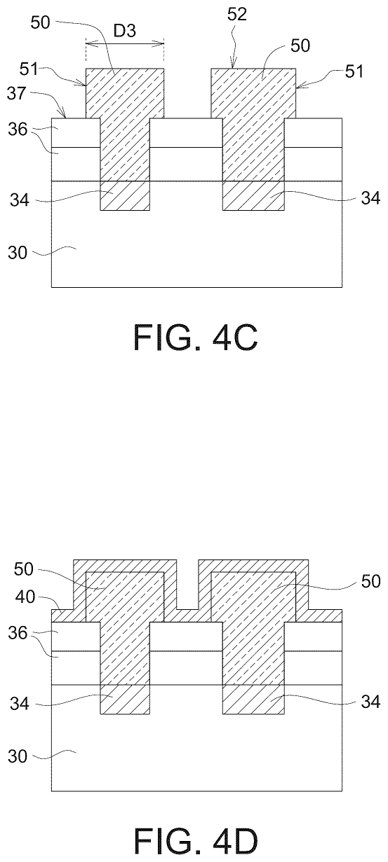

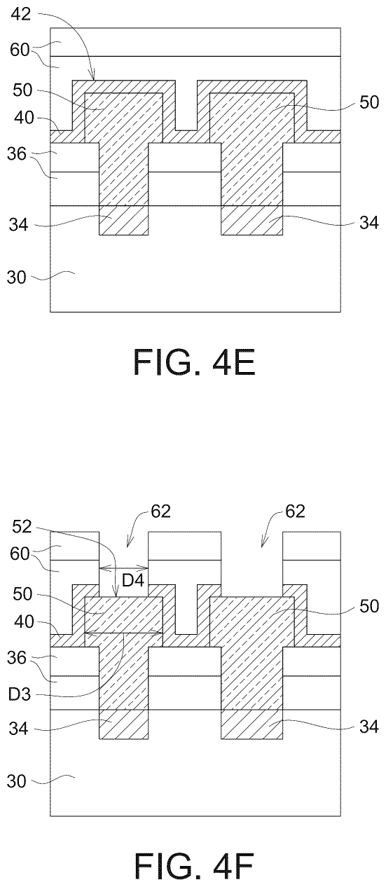

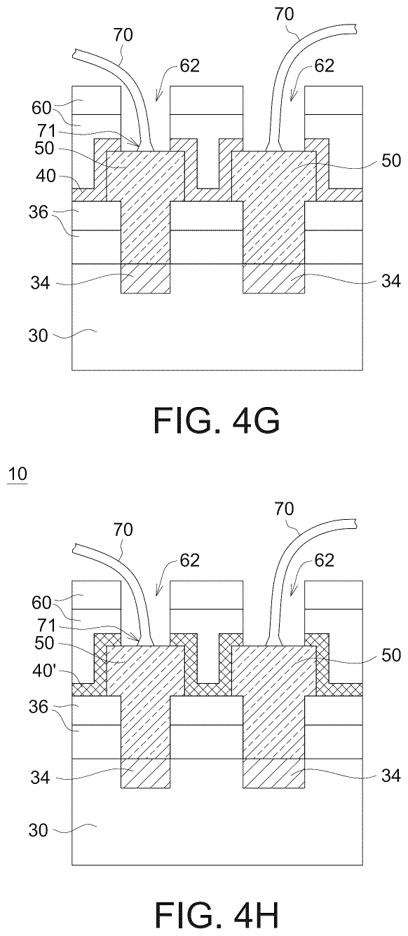

Referring to FIGS. 3A to 3B and FIGS. 4A to 4H, FIGS. 3A and 3B illustrate a flowchart of steps of a method for manufacturing a package structure 10 in accordance with an embodiment of the present disclosure. FIGS. 4A to 4H illustrate the steps for manufacturing the package structure 10 in FIGS. 3A and 3B.

Referring to step S210 of FIG. 3A and FIG. 4A, a semiconductor die 30 is formed, and the semiconductor die 30 includes a plurality of conductive pads 34, which are disposed on a first surface 31 of the semiconductor die 30. In addition, the semiconductor die 30 may include an integrated circuit (not shown), which is electrically connected to the conductive pads 34 by an internal connection layer (not shown).

The present disclosure is illustrated by an example of a sensor package, such as a package structure 10 for a fingerprint reader; however, it is to be appreciated that in the embodiment of the package structure 10 disclosed herein, it may be applied to electronic components of various integrated circuits 32. The conductive pads 34 may, for example, be made of copper (Cu), aluminum (Al), or other suitable metallic materials. In one embodiment, the semiconductor die 30 may be subjected to an electrical test by the conductive pads 34. The electrical test is performed, for example, by contacting the conductive pads 34 with a plurality of probes 80, which are used to input electrical signals to the integrated circuit 32 and receive electrical signals output from the integrated circuit 32 in order to test the electrical performance of the integrated circuit 32.

Referring to step S220 of FIG. 3A and FIG. 4A, after completing the electrical test, a first passivation layer 36 is formed on the first surface 31 of the semiconductor die 30, and the first passivation layer 36 covers the conductive pads 34. The first passivation layer 36 may comprise a single dielectric layer or multi-dielectric layers, and the dielectric layer may be silicon oxide, silicon nitride, silicon nitride oxide, or a combination of any of the above. The first passivation layer 36 can be formed using deposition processes such as atomic layer deposition (ALD), chemical vapor deposition (CVD), sputtering, and so forth. The first passivation layer 36 usually has a thickness of at least 10 nm, but in order to avoid burn-through and loss of passivation effect during the manufacturing process of electrodes, it is preferred to have a thickness of about 20 nm to 2000 nm, and more preferably from about 40 nm to 500 nm.

Referring to steps S230 of FIG. 3A and FIG. 4B, the first passivation layer 36 is patterned to expose top surfaces 35 of the conductive pads 34 in a plurality of first openings 38 of the first passivation layer 36, respectively. In one embodiment, the first passivation layer 36 may be patterned using photoresist exposure, developing, etching, or using laser light. In another embodiment, the first passivation layer 36 having the plurality of first openings 38 with a predetermined aperture D1 can be formed directly using a screen printing method, and the first passivation layer 36 with the predetermined pattern can be formed on the first surface 31 of the semiconductor die 30 by simply thermal treating (e.g., sintering with heat) without the need to additionally pattern the layer using photoresist exposure, developing, etching, or laser light. The aperture D1 of the first opening 38 is substantially equal to or smaller than the width D2 of the conductive pad 34.

Referring to step S240 of FIG. 3 and FIG. 4C, a plurality of bonding pads 50 are formed on the conductive pads 34, each of which is located in the first opening 38 and protrudes from the top surface 37 of the first passivation layer 36. The bonding pads 50 are, for example, metal pads, which are made of, for example, aluminum, aluminum alloy, copper, copper alloy, or a combination of any of the above. The bonding pads 50 may be formed in the first openings 38 of the first passivation layer 36 using a deposition process, and the top surface 52 of the bonding pads 50 is higher than the top surface 37 of the first passivation layer 36 and its side edges 51 protrude beyond the first openings 38 to cover the top surface 37 of the first passivation layer 36. In one embodiment, in order to obtain suitable bonding properties, the contours of the bonding pads 50 have a suitable step height and may be T-shaped. The T-shaped bonding pad 50 has an upper width D3 greater than the width D2 of the conductive pads 34.

Referring to step S250 of FIG. 3A and FIG. 4D, a phase change material layer 40 is formed on the top surface 37 of the first passivation layer 36, which is electrically coupled to the bonding pads 50. As shown in FIG. 4D, the phase change material layer 40 extends along the top surface 37 of the first passivation layer 36, the opposing side edges 51 of the bonding pads 50, and the top surfaces 52 of the bonding pads 50 and fully covers one side of the semiconductor die 30 so that all of the bonding pads 50 have the same potential.

The phase change material layer 40 is formed, for example, by physical vapor deposition, chemical vapor deposition, or atomic layer deposition. Before the semiconductor die 30 is packaged, the phase change material layer 40 is deposited on the top surface 37 of the first passivation layer 36 and electrically connected to the bonding pads 50 so that the bonding pads 50 have the same electrical potential. Since all of the bonding pads 50 have the same potential, even if one of the bonding pads 50 on the semiconductor die 30 is subjected to an electrostatic discharge attack during die packaging, the electrostatic discharge can still be transmitted to the other bonding pads 50 through the phase change material layer 40, and dielectric breakdown that could damage the integrated circuit 32 can be avoided.

In one embodiment, the phase change material layer 40 includes a conductive material, such as a metal alloy, which electrically connects all of the conductive pads 34 to a ground wire to conduct the incoming electrostatic current to the ground. The phase change material layer 40 is, for example, a GeSbTe alloy, a SbTe alloy, or BN, etc. In an embodiment, the phase change material layer 40 may has a phase change between a crystalline state and an amorphous state to change the resistance value. When the phase change material layer 40 is in the crystalline state, the resistance is low so that the electrical conductivity is good; when the phase change material layer 40 is in the amorphous state, the resistance is high so that the electrical conductivity is poor. That is, when the phase change material layer 40 is in the crystalline state, it has electrical conductivity, and when the phase change material layer 40′ is in the amorphous state, it has electrical insulation.

Referring to step S260 of FIG. 3B and FIG. 4E, a second passivation layer 60 is formed on the first passivation layer 36, and the second passivation layer 60 covers the phase change material layer 40, i.e., the phase change material layer 40 is deposited between the first passivation layer 36 and the second passivation layer 60 and between the bonding pads 50 and the second passivation layer 60. The second passivation layer 60 may comprise a single dielectric layer or multiple dielectric layers, which may be silicon oxide, silicon nitride, silicon nitride, silicon nitride or any combination thereof. The second passivation layer 60 may be formed using deposition processes such as atomic layer deposition (ALD), chemical vapor deposition (CVD), sputtering, and the like. The second passivation layer 60 normally has a thickness of at least 10 nm, preferably from about 20 nm to 2000 nm, and more preferably from about 40 nm to 500 nm.

Referring to step S270 of FIG. 3B and FIG. 4F, the second passivation layer 60 and the phase change material layer 40 are patterned to expose the top surfaces 52 of the bonding pads 50 in a plurality of second openings 62 of the second passivation layer 60, respectively. In one embodiment, the patterned second passivation layer 60 and the phase change material layer 40 may be patterned using photoresist exposure, developing, etching or using laser light. In another embodiment, the second passivation layer 60 having the plurality of second openings 62 with a predetermined aperture D4 can be formed directly using a screen printing method by simply thermal treating (e.g., heat sintering) the coating layer to form the second passivation layer 60 with the pre-determined pattern on the top surface of the second passivation layer 60 without the need to additionally pattern the layer using photoresist exposure, developing, etching, or using laser light. The second passivation layer 60 is formed with the predetermined pattern without the need for additional photoresist exposure, developing, etching or patterning using laser light. The aperture D4 of the second openings 62 is substantially equal to or smaller than the upper width D3 of the bonding pads 50.

As shown in FIGS. 4E and 4F, in one embodiment, a top portion 42 of the phase change material layer 40 over the top surface 52 of the bonding pads 50 may be removed by etching, and each of the top surfaces 52 of the bonding pads 50 may be etched to form a recessed surface 54, respectively. However, the top portion 42 of the phase change material layer 40 may also be retained on each of the top surfaces 52 of the bonding pads 50.

Referring to step S280 of FIG. 3B and FIG. 4G, a packaging process is performed so that a conductive feature 70 is formed on each of the bonding pads 50 of the semiconductor die 30, one end 71 of the conductive feature 70 is bonded to the semiconductor die 30, and the other end of the conductive feature 70 is bonded to a carrier 20 (see FIG. 5). The packaging process may be a wire bonding process or a flip-chip packaging process. The conductive feature 70 may be a wire (e.g., gold or aluminum wire) or a conductive bump (e.g., copper alloy). Taken a wire bonding process as example, a wire bonder is used to fuse one end of the wire into a ball and penetrates the phase change material layer 40 to bond with a corresponding bonding pad 50, and then the other end of the wire is pulled onto the carrier 20 to bond with a corresponding pin 22 of the carrier 20.

Referring to step S290 of FIG. 3 and FIG. 4H, an annealing process is performed to change the crystal of the phase change material layer 40 from a crystalline state to an amorphous state, and to change the electrical property of the phase change material layer 40 from a low resistance to a high resistance. The amorphous phase change material layer 40′ has a resistance value that is much higher than the resistance value of the crystalline phase change material layer 40. In addition, the amorphous phase change material layer 40 has, in addition to a high resistance value, a low dielectric constant, such as smaller than a dielectric constant of silicon (about 3.5), to reduce the overall dielectric constant of the dielectric material.

As shown in FIG. 4H, the phase change material layer 40 undergoes a thermal treatment (e.g., annealing) and changes to an amorphous state, which causes the bonding pads 50 to be electrically insulated from each other due to the high resistance value. The amorphous phase change material layer 40′ can be used as an electrostatic discharge (ESD) protection layer overlying the top surface 37 of the first passivation layer 36.

The present disclosure relates to a package structure and a method for manufacturing the same. A phase change material layer is provided on a semiconductor die that includes an integrated circuit. The phase change material layer is formed of a material whose crystal changed from a crystalline state to an amorphous state, and whose electrical property changed from a low resistance to a high resistance when the phase change material layer is annealed. The phase change material layer connects all of conductive pads or bonding pads of the semiconductor die during assembly of the package structure so as to significantly improve the ESD protection capability of the semiconductor die.

According to some embodiments of the present disclosure, a package structure includes a semiconductor die and a carrier. The semiconductor die has a first surface, an electrostatic discharge protection layer, and a plurality of conductive pads disposed on the first surface, and the electrostatic discharge protection layer covers the conductive pads. The semiconductor die is disposed on the carrier, and the semiconductor die is electrically connected to the carrier by a plurality of conductive features. One end of the conductive features penetrates the electrostatic discharge protection layer to bond with the semiconductor die, and another end of the conductive features is bonded to the carrier.

According to some embodiments of the present disclosure, a method for manufacturing a package structure includes the following steps. A semiconductor die is formed, the semiconductor die including a plurality of conductive pads disposed on a first surface of the semiconductor die. An electrical test is performed on the semiconductor die by the conductive pads. A phase change material layer is formed on the first surface of the semiconductor die, and the phase change material layer is electrically connected to the conductive pads. A packaging process is performed to form a conductive feature on the conductive pads of the semiconductor die. One end of the conductive feature penetrates the phase change material layer. An annealing process is performed to change the crystal of the phase change material layer from a crystalline state to an amorphous state, and to change the electrical property of the phase change material layer from a low resistance to a high resistance.

According to some embodiments of the present disclosure, a method for manufacturing a package structure includes the following steps. A semiconductor die is formed, the semiconductor die includes a plurality of conductive pads, and the conductive pads are disposed on a first surface of the semiconductor die. A phase change material layer is formed on one side of the semiconductor die, and the phase change material layer is electrically connected to the conductive pads. A plurality of bonding pads is formed on the side of the semiconductor die, the bonding pads are correspondingly disposed on the conductive pads. A phase change material layer is formed on the side of the semiconductor die, and the phase change material layer is electrically connected to the bonding pads. A packaging process is performed to form a conductive feature on each of the bonding pads of the semiconductor die, wherein one end of the conductive feature is bonded to the semiconductor die by penetrating the phase change material layer. An annealing process is performed to change the phase change material layer from a crystalline state to an amorphous state, and to change the electrical property of the phase change material layer from a low resistance to a high resistance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a package structure, comprising:
forming a semiconductor die, the semiconductor die comprising at least a conductive pad disposed on a first surface of the semiconductor die;
forming a phase change material layer on the first surface of the semiconductor die, the phase change material layer being electrically connected to the conductive pad;
forming a conductive feature on the conductive pad of the semiconductor die, the conductive feature penetrating the phase change material layer; and
performing an annealing process to change the phase change material layer from a crystalline state to an amorphous state.

2. The method of claim 1, wherein forming the semiconductor die further comprises performing an electrical test on the semiconductor die by the conductive pads.

3. The method of claim 1, wherein the conductive feature comprises a wire, and forming the conductive feature comprises performing a wire bonding process to bond an end of the wire to the semiconductor die.

4. The method of claim 1, wherein the conductive feature comprises a conductive bump, and forming the conductive feature comprises performing a flip-chip packaging process to bond an end of the conductive bump to the semiconductor die.

5. The method of claim 1, wherein the phase change material layer is changed from a low resistance to a high resistance when the phase change material layer is changed from the crystalline state to the amorphous state.

6. The method of claim 1, wherein the phase change material layer comprises GeSbTe alloy or SbTe alloy.

7. The method of claim 1, wherein the annealing process comprises heating the phase change material layer in the crystalline state to a phase change temperature and rapidly cooling the phase change material layer to convert the phase change material layer to the amorphous state.

8. A method for manufacturing a package structure, comprising:
forming a semiconductor die, the semiconductor die comprising at least a first conductive feature disposed on a first surface of the semiconductor die;
forming at least a bonding pad on the semiconductor die, the bonding pad being correspondingly disposed on the first conductive feature;
forming a phase change material layer on the bonding pad, the phase change material layer electrically connected to the bonding pad;
forming a second conductive feature on the bonding pad of the semiconductor die, wherein one end of the conductive feature is bonded to the semiconductor die; and
performing an annealing process to change the phase change material layer to an amorphous state.

9. The method of claim 8, wherein forming the semiconductor die further comprises:
forming a first passivation layer on the first surface of the semiconductor die, the first passivation layer covering the first conductive feature;
patterning the first passivation layer to expose top surfaces of the conductive pads in a plurality of first openings of the first passivation layer; and
forming the bonding pads on the first conductive feature, the bonding pads being disposed in the first openings and protruding from a top surface of the first passivation layer, respectively.

10. The method of claim 9, further comprising:
forming a second passivation layer on the first passivation layer, the second passivation layer covering the phase change material layer; and
patterning the second passivation layer to expose the bonding pads in a plurality of second openings of the second passivation layer, respectively.

11. The method of claim 10, wherein patterning the second passivation layer further comprises removing a top portion of the phase change material layer overlying top surfaces of the bonding pads.

12. The method of claim 8, wherein forming the semiconductor die further comprises performing an electrical test to the semiconductor die by the fist conductive feature.

13. The method of claim 8, wherein the conductive feature comprises a wire, forming the second conductive feature comprising performing a wire bonding process to bond an end of the wire to the semiconductor die.

14. The method of claim 8, wherein the conductive feature comprises a conductive bump, and forming the second conductive feature comprises performing a flip-chip packaging process to bond an end of the conductive bump to the semiconductor die.

15. The method of claim 8, wherein the phase change material layer is changed from a low resistance to a high resistance when the phase change material layer is changed from the crystalline state to the amorphous state.

16. The method of claim 8, wherein the phase change material layer comprises GeSbTe alloy or SbTe alloy.

17. The method of claim 8, wherein the annealing process comprises heating the phase change material layer in the crystalline state to a phase change temperature and rapidly cooling the phase change material layer to convert the phase change material layer to the amorphous state.

18. A package structure, comprising:
a semiconductor die,
wherein the semiconductor die having a first surface, an electrostatic discharge protection layer, and a plurality of conductive pads, the conductive pads being disposed on the first surface and the electrostatic discharge protection layer covering the conductive pads, the semiconductor die being electrically coupled to a carrier by a plurality of conductive features, wherein one end of the conductive features penetrates the electrostatic discharge protection layer to bond with the semiconductor die, and another end of the conductive features is bonded to the carrier.

19. The package structure of claim 18, wherein the carrier is for carrying the semiconductor die, the electrostatic discharge protection layer is a phase change material layer, wherein the phase change material layer is changed from a low resistance to a high resistance when the phase change material layer is changed from a crystalline to an amorphous state.

20. The package structure of claim 19, wherein the phase change material layer in the amorphous state is electrically insulated from the conductive pads.
